(19) United States
(12) Patent Application Publication
(10) Pub. No.: US 2019/0157509 A1
(43) Pub. Date: May 23, 2019

(54) GaN SUBSTRATE AND FABRICATION METHOD THEREFOR

(71) Applicant: Panasonic Intellectual Property Management Co., Ltd., Osaka (JP)

(72) Inventors: Isao TASHIRO, Osaka (JP); Hidenao KATAOKA, Osaka (JP); Nobuyuki YOKOYAMA, Osaka (JP); Takeshi OHMORI, Osaka (JP)

(21) Appl. No.: 16/181,777

(22) Filed: Nov. 6, 2018

(30) Foreign Application Priority Data
Nov. 22, 2017 (JP) 2017-225119

(51) Int. Cl. H01L 33/32; H01L 33/00

(52) U.S. Cl. CPC H01L 33/32; H01L 33/0075

(57) ABSTRACT

A GaN substrate that comprises a GaN single crystal having a Ga face and a N face on surfaces thereof, wherein the Ga face includes: a flat face portion; and a curved face portion that surrounds a circumference of the flat face portion, and wherein an off-angle distribution of the N face is larger than an off-angle distribution of the Ga face.

### CROSS-REFERENCE TO RELATED APPLICATIONS

This application claims priority of Japanese Patent Application No. 2017-225119 filed on Nov. 22, 2017, the contents of which is incorporated herein by reference.

### BACKGROUND OF THE INVENTION

### (1) Field of the Invention

The present disclosure relates to a GaN substrate and a fabrication method of the GaN substrate.

### (2) Description of the Related Art

GaN is a semiconductor that has features of a short bond length between its constituent atoms and a large band gap compared to those of each of the traditional semiconductor materials represented by Si. Epitaxial growth is first conducted for a GaN free-standing substrate as a process to form a structure of an optical device or a power device on a GaN substrate. When the epitaxial growth surface is constituted by a single (0001) surface, a portion may be present in the epitaxial growth surface to be a seed of contingent crystal growth such as a fault or a foreign object. In this case, when vapor phase epitaxy of GaN is conducted for the epitaxial growth surface using, for example, a MOCVD method, Ga atoms may aggregate to each seed of the contingent crystal growth and locally uneven growth may occur. To prevent the locally uneven growth, a method is present according to which an off-angle inclined by a certain angle relative to the crystal direction is set for the epitaxial growth surface to artificially produce an atomic step. The Ga raw material is thereby partially bonded with methyl groups and, in this state, moves in the (0001) surface (migration of Ga raw material) that is the epitaxial growth surface when the vapor phase epitaxy of GaN is conducted on the GaN substrate using the MOCVD method. When a stable position is present, the Ga raw material stops at the position and releases the bond with the methyl groups to be bonded with N for the epitaxial growth to thereby be continued. The epitaxial growth can therefore be stabilized by setting the off-angle in the epitaxial growth surface and utilizing the steps adjacent to each other as the stable positions. In addition, when the epitaxial growth is conducted, an advantage is present that even and clean growth can be conducted. Japanese Patent Publication No. 5496007 describes a GaN substrate with the off-angle.

Japanese Patent Publication No. 5496007 describes a GaN substrate including a GaN (0001) surface that is off-cut at an angle of 0.2 to 10 degrees from a [0001] direction and a GaN (000-1) surface that is off-cut at an angle of 0.2 to 10 degrees from a [000-1] direction. The off-cut GaN (0001) surface is parallel to the off-cut GaN (000-1) surface and form the GaN substrate having a lattice curvature as a whole.

A GaN crystal can be formed on a foundation substrate represented by sapphire using a vapor phase epitaxial method such as, for example, a hydride vapor phase epitaxial method (an HVPE method) or a metal organic chemical vapor deposition method (an MOCVD method). In the GaN crystal grown on a hetero substrate, warpage is however generated that is originated from the difference in the lattice constant or the difference in the thermal expansion between GaN substrate and the hetero substrate that is the foundation substrate, and warpage of the crystal is thereby generated. When the foundation substrate is cut off from the GaN free-standing substrate having the foundation substrate to obtain the GaN free-standing substrate alone, then, the GaN free-standing substrate is processed to have parallel flat faces, the physical shape of the substrate surface is the flat face while dispersion of the off-angle, that is, an off-angle distribution is generated because warpage is generated in the crystal. When the dispersion of the off-angle is generated, locally uneven growth occurs in the epitaxial growth or no stable growth may be acquired. For example, for an optical device, dispersion of the property of the device structure finally occurs and this derives as a dispersion of the light emission wavelength.

As described in Japanese Laid-Open Patent Publication No. 2009-126727, a method of reducing the off-angle dispersion is proposed. As depicted in FIG. 20, the center of a GaN substrate 101 is denoted by “P₀” and a point inward by 5 mm or longer from an end face of the GaN substrate 101 is denoted by “P1”. At the center P₀, a normal line of the substrate surface is denoted by “n₀” and the direction of a crystal axis x₀ is denoted by “a₀”. An angle is denoted by “angle α₀” that is formed by the normal line n₀ of the substrate surface at the center P₀ and the crystal axis a₀. Similarly, at P1, the normal line of the substrate surface is denoted by “n₁”, the direction of a crystal axis x₁ is denoted by “a₁”, and an angle is denoted by “angle α₁” that is formed by the normal line n₁ and the direction a₁ of the crystal axis. A fabrication method for the GaN substrate 101 includes a step of processing the surface of the substrate 101 that includes a GaN single crystal to have a concave spherical surface based on the dispersion of each of the directions a₀ and a₁ of the crystal axes x₀ and x₁ in the surface of the substrate 101. The dispersion of each of the directions a₀ and a₁ of the crystal axes x₀ and x₁ relative to the normal lines n₀ and n₁ is reduced in the surface of the GaN substrate 101 after the processing, by processing the surface of the GaN substrate 101 to have the concave spherical surface.

### SUMMARY

FIG. 1 and FIG. 2 each depict a result of measurement of an off-angle distribution of a 2-inch GaN substrate fabricated using the Hydride Vapor Phase Epitaxy (HVPE) method, using an X-ray diffractometer D8 DISCOVER manufactured by BRUKER Co., Ltd. The axis of abscissa represents a position (mm) on the substrate when the substrate center is set to be 0 mm, and the axis of ordinate represents the angle (deg) that is the difference from the formed off-angle, that is, the off-angle distribution. In the case where the X-axis direction is set as a [1-100] direction and the Y-axis direction is set as a [11-20] direction as depicted in FIG. 3, FIG. 1 depicts the measurement result of the off-angle distribution on the X-axis line (a line 1) and FIG. 2 depicts the measurement result of the off-angle distribution on the Y-axis line (a line 2). This GaN substrate is, for example, a substrate that has an off-angle of 0.4 deg formed therein in a [1-100] direction, and the off-angle is 0 deg in the [11-20] direction. As depicted in FIG. 1, the off-angle distribution relative to the off-angle of 0.4 deg formed in the X-axis direction has a distribution in the X-axis direction. As depicted in FIG. 2, the off-angle distribution relative to the off-angle of 0 deg formed in the Y-axis direction has a distribution in the Y-axis direction. As depicted in FIG. 1 and FIG. 2, the off-angle distribution becomes larger as the measurement position becomes closer to the outer circumference. The off-angle distribution is represented as angles in FIG. 1 and FIG. 2 while, when the off-angle distribution is represented as the distance that indicates the warpage of the crystal for each of four directions depicted in FIG. 4, concave shapes as depicted in FIG. 5 are acquired, and the difference in the height for the width of 2 inches (50 mm) is 0.1 mm or larger. To set the off-angle distribution to be 0 deg, it is an option to form the shape of the surface to be same as the warpage of the crystal as depicted in FIG. 5.

Having the difference in the height of the substrate surface of 0.1 mm or larger means having the total thickness variation (TTV) of 0.1 mm or larger. When this substrate is used, at the steps of fabricating the device, a failure such as defocusing may however occur when an exposure process is conducted to form the pattern of each of the device structure and the wiring structure on the side of the epitaxial growth surface. In the back-grinding to reduce the thickness of the GaN substrate, because the back face is processed to have a flat face shape, devices having different thicknesses may be fabricated due to the total thickness variation and dispersion of the device property may be generated depending on the location (the thickness).

When the method described in Japanese Laid-Open Patent Publication No. 2009-126727 is applied according to which the surface is processed to have a spherical face shape to reduce the off-angle distribution, as depicted in FIG. 5, the difference in the height of about 60 μm is present as the warpage of the crystal at a position of a radius of 20 mm. When the off-angle distribution in this case is about 0.5 deg, the substrate surface acquired when the off-angle distribution is set to be 0.25 deg that is ½ of the above as depicted in FIG. 6 has the difference in the height of about 30 μm as depicted in FIG. 7. When the off-angle distribution is further reduced, the difference in the height of the substrate surface becomes larger and it is therefore difficult to further reduce the off-angle distribution and the difference in the height of the substrate surface.

One non-limiting and exemplary embodiment provides a GaN substrate having a reduced off-angle distribution and a reduced difference in the height of the substrate surface.

In one general aspect, the techniques disclosed here feature: a GaN substrate that comprises a GaN single crystal having a Ga face and a N face on surfaces thereof, wherein the Ga face includes:

a flat face portion; and

a curved face portion that surrounds a circumference of the flat face portion, and

wherein an off-angle distribution of the N face is larger than an off-angle distribution of the Ga face.

According to the present disclosure, the GaN substrate having a reduced off-angle distribution and reduced total thickness variation can be provided.

Additional benefits and advantages of the disclosed embodiments will be apparent from the specification and figures. The benefits and/or advantages may be individually provided by the various embodiments and features of the specification and drawings disclosure, and need not all be provided in order to obtain one or more of the same.

### BRIEF DESCRIPTION OF THE DRAWINGS

The present disclosure will become readily understood from the following description of non-limiting and exemplary embodiments thereof made with reference to the accompanying drawings, in which like parts are designated by like reference numeral and in which:

FIG. 1 is a diagram of an off-angle distribution of a GaN substrate;

FIG. 2 is a diagram of an off-angle distribution of the GaN substrate;

FIG. 3 is an explanatory diagram of directions for X-ray diffraction measurement of the GaN substrate;

FIG. 4 is an explanatory diagram of directions for the X-ray diffraction measurement of the GaN substrate;

FIG. 5 is a diagram of warpage of a crystal of the GaN substrate;

FIG. 6 is a diagram of the off-angle distribution of the GaN substrate;

FIG. 7 is a diagram of the warpage of the crystal and the surface shape of the GaN substrate;

FIG. 8A is an explanatory diagram of a step of fabrication method of the GaN substrate;

FIG. 8B is an explanatory diagram of a step of the fabrication method of the GaN substrate;

FIG. 8C is an explanatory diagram of a step of the fabrication method of the GaN substrate;

FIG. 8D is an explanatory diagram of a step of the fabrication method of the GaN substrate;

FIG. 9 is a three-dimensional diagram of a jig;

FIG. 10 is a diagram of the measurement result of the surface shape of the GaN substrate;

FIG. 11 is a diagram of the off-angle distribution of the GaN substrate;

FIG. 12 is a diagram of the off-angle distribution of the GaN substrate;

FIG. 13 is a three-dimensional diagram of the shape of the GaN substrate;

FIG. 14 is a diagram of the surface shape of a GaN substrate according to a first embodiment;

FIG. 15A is an explanatory diagram of a step of fabrication method of the GaN substrate according to the first embodiment;

FIG. 15B is an explanatory diagram of a step of the fabrication method of the GaN substrate according to the first embodiment;

FIG. 15C is an explanatory diagram of a step of the fabrication method of the GaN substrate according to the first embodiment;

FIG. 15D is an explanatory diagram of a step of the fabrication method of the GaN substrate according to the first embodiment;

FIG. 16 is a diagram of the off-angle distribution of the GaN substrate according to the first embodiment;

FIG. 17 is a diagram of the off-angle distribution of the GaN substrate according to the first embodiment;

FIG. 18 is a diagram of the off-angle distribution of the GaN substrate;

FIG. 19A is an explanatory diagram of a step of fabrication method of a GaN substrate according to a modification example of the first embodiment;

FIG. 19B is an explanatory diagram of a step of the fabrication method of the GaN substrate according to the modification example of the first embodiment;

FIG. 19C is an explanatory diagram of a step of the fabrication method of the GaN substrate according to the modification example of the first embodiment;

FIG. 19D is an explanatory diagram of a step of the fabrication method of the GaN substrate according to the modification example of the first embodiment; and

FIG. 20 is an explanatory diagram of a traditional GaN substrate.

### DETAILED DESCRIPTION

A GaN substrate that comprises a GaN single crystal having a Ga face and a N face on surfaces thereof according to a first aspect, wherein the Ga face comprises:

a flat face portion; and

a curved face portion that surrounds a circumference of the flat face portion, and

wherein an off-angle distribution of the N face is larger than an off-angle distribution of the Ga face.

Further, as a GaN substrate of a second aspect, in the first aspect, wherein the off-angle distribution θ1 of the Ga face is 0.25 deg or smaller, and

wherein a total thickness variation t1 of the GaN substrate is 20 μm or smaller.

A fabrication method for a GaN substrate according to a third aspect, the fabrication method comprising:

preparing a GaN substrate that comprises a GaN single crystal having a Ga face and a N face, the Ga face and the N face being parallel to each other on principal surfaces of the GaN substrate, the principal surfaces facing each other;

causing the N face to face a surface of a jig that comprises a flat face portion at a center thereof and a curved face portion surrounding a circumference of the flat face portion to attach the GaN substrate to the jig;

polishing the Ga face of the GaN substrate to have a flat face shape; and

detaching the jig from the GaN substrate.

Further, as a fabrication method for a GaN substrate of a fourth aspect, in the third aspect, wherein in the case where warpage of the crystal of the prepared GaN substrate comprises a concave shape when seen from the Ga face, the jig comprises a convex shape that comprises the flat face portion at the center protruded relative to the curved face portion on an outer edge thereof, on the surface thereof.

Further, as a fabrication method for a GaN substrate of a fifth aspect, in the third aspect, wherein in the case where warpage of the crystal of the prepared GaN substrate comprises a convex shape when seen from the Ga face, the jig comprises a concave shape having the curved face portion on an outer edge thereof protruded relative to the flat face portion at the center thereof, on the surface thereof.

Further, as a fabrication method for a GaN substrate of a sixth aspect, in the third aspect, wherein a section of the jig corresponding to a section in a range for an off-angle distribution θ1 from the center of the Ga face of the prepared GaN substrate is set to be the flat face portion.

Further, as a fabrication method for a GaN substrate of a seventhth aspect, in the third aspect, wherein the jig comprises a reference face having a flat face shape on a back face thereof that faces the surface, and

wherein at the step of polishing, the Ga face is polished to have a flat face shape to be in parallel to the reference face of the jig.

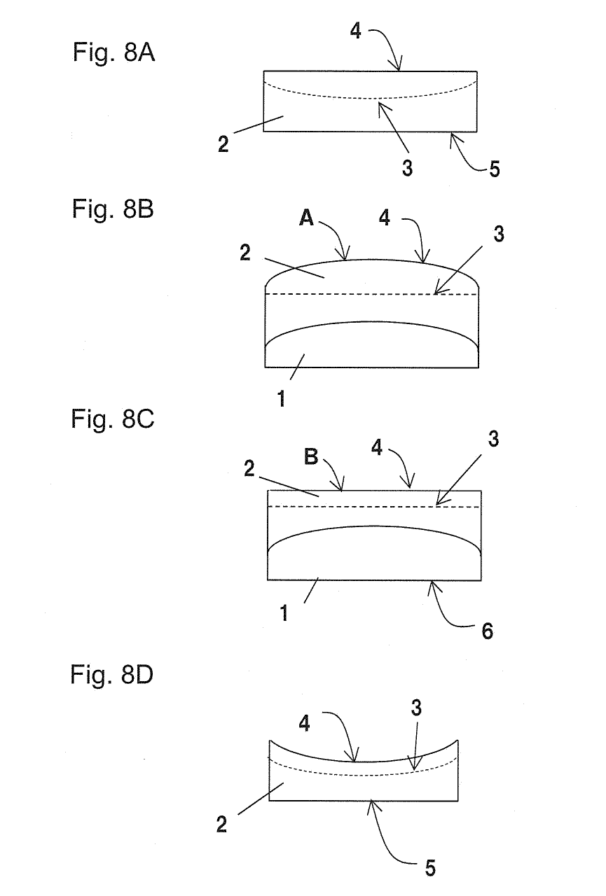

A GaN substrates according to an embodiment will be described with reference to FIG. 8A to FIG. 19D. In the drawings, substantially same members are given the same reference numerals.

### First Embodiment

### <Details of Completion of GaN Substrate and Fabrication Method Therefor of the Present Disclosure>

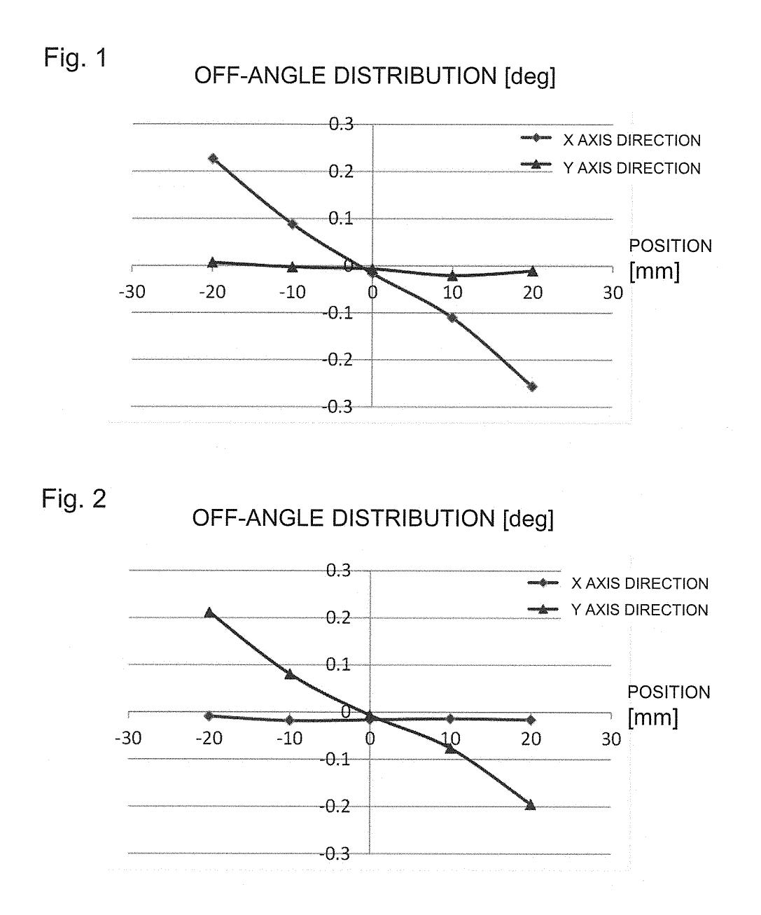

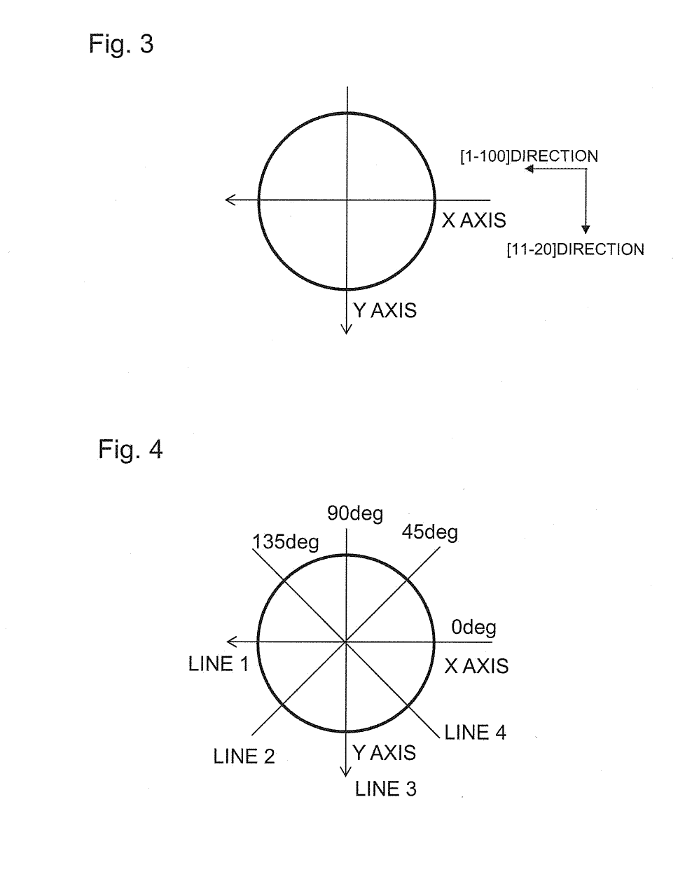

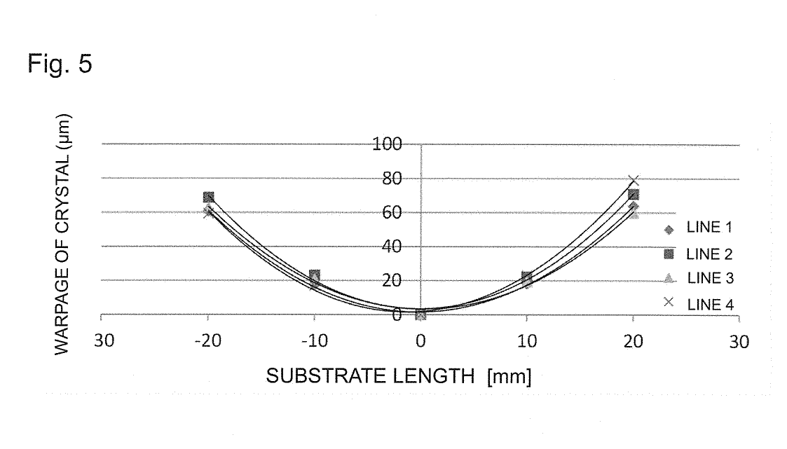

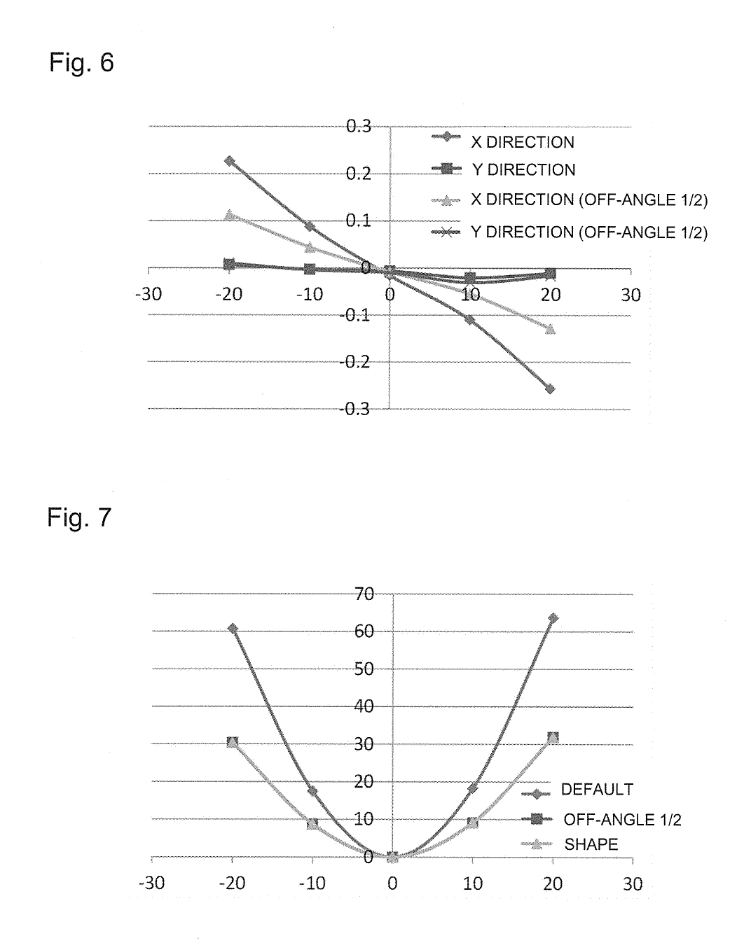

FIG. 1 and FIG. 2 are each a diagram of the off-angle distribution of a GaN substrate. As depicted in FIG. 1 and FIG. 2, an off-angle distribution is generated by warpage of the crystal. To set the off-angle distribution of the GaN substrate to be zero, the surface only has to be processed being matched with the shape of the warpage of the crystal. A difference in the height (the thickness distribution) of 60 μm or larger is however generated by processing the surface to have a concave shape that has a difference in the height of 60 μm or larger between the outer edge and the center. As above, in this state, a failure occurs in steps of forming a device. To reduce this total thickness variation, the shape of a N face only has to be processed to be the same shape as that of a Ga face (a convex shape when seen from the N face). In this case, the off-angle distribution of the N face also becomes zero.

At steps of epitaxial growth using the GaN substrate, a problem may arise in the installation of the GaN substrate to a susceptor in the case where the shape of the N face is, for example, a convex when seen from the N face. For example, when the GaN substrate is placed to lie on the N face thereof on the susceptor used for the epitaxial growth, a temperature distribution may be generated because a distance is established between the susceptor and the N face, and a dispersion is generated in the properties of the grown film. As a result, variation of the wavelength of the device is generated. The N face therefore only has to be able to be installed on the susceptor and the off-angle distribution of the N face only has to be larger than the off-angle distribution of the Ga face. For example, the degree of flatness of the N face may be maintained because the function for the N face may not provide reduction of the off-angle distribution.

The off-angle distribution in the range of ±10 mm from the center to be the range in which the off-angle distribution of the Ga face is 0.25 deg in FIG. 1 and FIG. 2 is admitted and processing for this portion to match with the shape of the warpage of the crystal is not conducted, that is, the surface processing amount is set to be 0 μm. In this case, in four directions that are at 0 deg, 45 deg, 90 deg, and 135 deg from the x-axis depicted in FIG. 4, when approximation is conducted using a quadratic function representing the length of the substrate on the x-axis and the processing amount on the y-axis, results are acquired as Eq. (1) to Eq. (4). When Eq. (1) to Eq. (4) are plotted in a chart, the shapes thereof substantially overlap on each other and it can be stated that the overall circumference have the same shape. Designing of a jig 1 described later can therefore be made easy by approximating Eqs. (1) to (4) into one equation.

Line 1: y=0.0718x²+0.1584x−3.774 (1)

Line 2: y=0.0454x²+0.0545x−2.726 (2)

Line 3: y=0.0514x²−0.1040x−3.082 (3)

Line 4: y=0.0596x²+0.2290x−3.577 (4)

For example, the average values of the coefficients in Eqs. (1) to (4) are calculated and, assuming that the surface is a curved face whose overall circumference has the same shape, the shape can be represented as a shape acquired by developing an approximated equation of Eq. (5) for 360 deg.

y=0.0571x²+0.0845x−3.2898 (5)

The processing method for a GaN substrate 2 will be described with reference to FIG. 8A to FIG. 8D.

(a) FIG. 8A is a cross-sectional diagram of the configuration of the GaN substrate 2 that has the off-angle distribution. The GaN substrate 2 is already processed to have the Ga face 4 and the N face 5 of the GaN substrate 2 fabricated using an HVPE method established to be parallel to each other by grinding. In FIG. 8A, the warpage 3 of the crystal is schematically indicated by a dotted line, that is generated in the GaN substrate and that has a shape of a convex from the Ga face 4 toward the N face. The warpage 3 of the crystal has a shape of a concave when seen from the side of the Ga face 4.

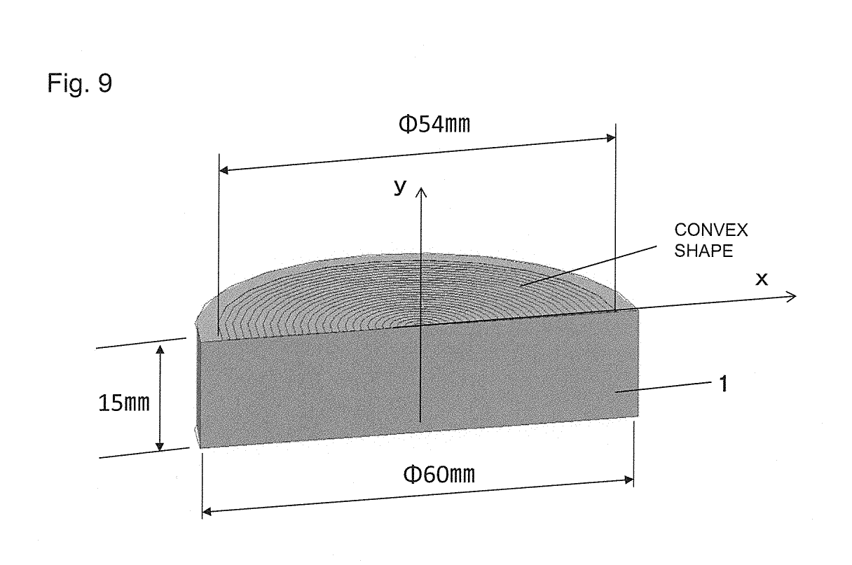

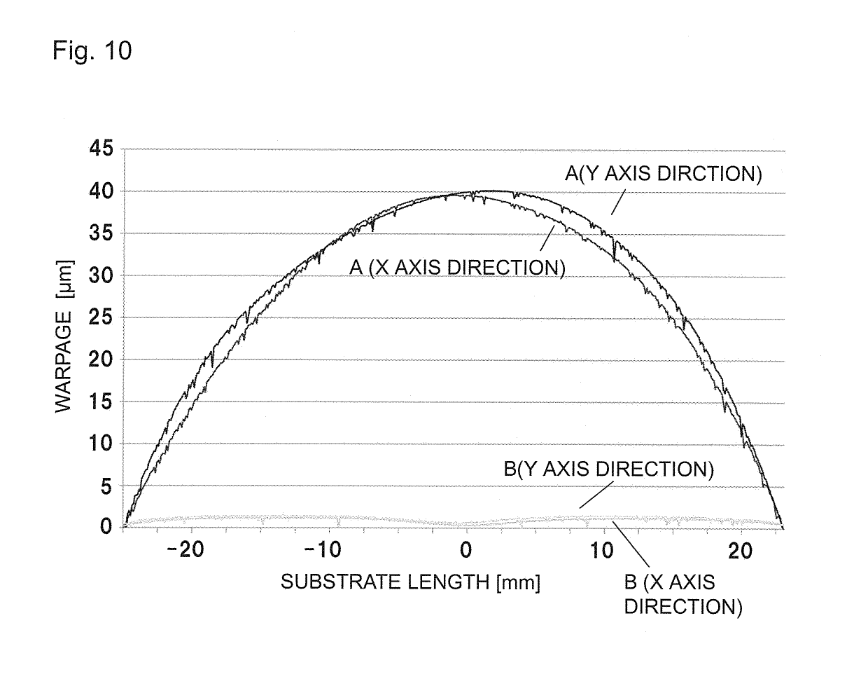

(b) As depicted in FIG. 8B, the N face 5 of the GaN substrate 2 is pressed to a jig 1 and a load is applied thereto to thereby deform the GaN substrate 2 to fit with the shape of the jig to be attached using a wax. As depicted in FIG. 9, the jig 1 is formed to have a convex shape with which a curved line passing through the center coordinates (0,0) has a shape of a cross-section represented by Eq. (5). Because the GaN substrate is pressed to the jig 1, ceramic, an iron-based material, or stainless steel is advantageously used as the material quality of the jig 1. For the attaching of the jig 1 and the GaN substrate 2 to each other, for example, the jig 1 is heated using a hot plate, a thermoplastic wax is applied to the surface of the jig 1, the GaN substrate 2 is placed thereon for the N face 5 and the jig 1 to be in contact with each other, a load is applied thereto, and, in this state, the wax is hardened by natural cooling. The result of acquisition is depicted in FIG. 10, of a shape “A” of the Ga face 4 of the GaN substrate 2 in this state using a laser reflection length measuring machine (NH-3MA manufactured by Mitaka Kohki Co., Ltd.) on the X- and Y-axes perpendicular to each other in a plain.

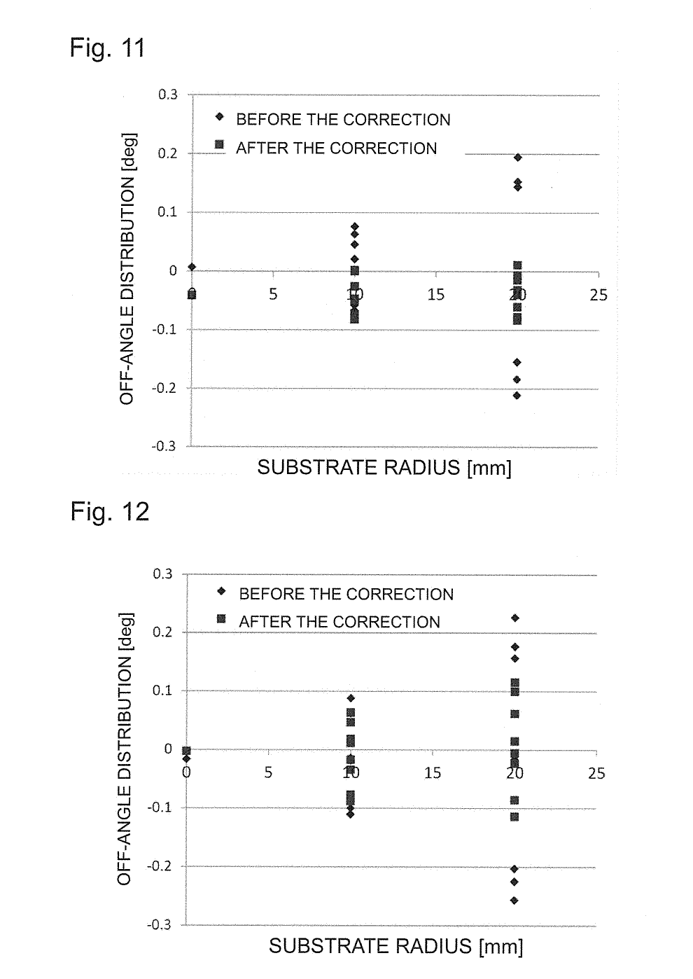

(c) As depicted in FIG. 8C, the Ga face 4 is ground to be parallel to a reference face 6 of the jig 1 and is further polished to remove an affected layer. For the grinding, parallel faces are formed by grinding using a rotary grindstone, and the degree of surface roughness is reduced by lapping using loose grains, surface honing using a fixed grindstone, or the like to remove the affected layer using chemical mechanical polishing (CMP) or the like. The surface shape of a shape B in this case is depicted in FIG. 10, the off-angle distribution therein is depicted in FIG. 11 and FIG. 12. FIG. 11 and FIG. 12 depict the result of measurement of the off-angle distribution before the correction of the off-angle (before polishing) and after the correction of the off-angle (after the polishing) of the GaN substrate 2 at intervals of 45 deg at radii of 0 mm, 10 mm, and 20 mm. FIG. 11 depicts the result in the x-axis direction and FIG. 12 depicts the result in the Y-axis direction. After the correction, the off-angle distribution is 0.25 deg or smaller within the substrate radius of 20 mm.

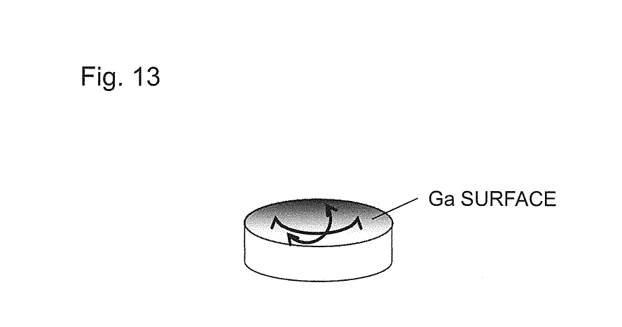

(d) Because the GaN substrate 2 is tightly attached to the jig 1 in the state of FIG. 8C, the jig 1 and the GaN substrate 2 are therefore heated using a hot plate to soften the wax, and the jig 1 and the GaN substrate 2 are separated from each other to acquire the GaN substrate 2 depicted in FIG. 8D. In this case, as depicted in FIG. 8D, the Ga face 4 is a concave and the N face 5 is a flat face. The shape as depicted in FIG. 13 is acquired by three-dimensionally depicting the GaN substrate 2. The difference in the height of the Ga face 4 in this case is about 40 μm between the center and the outer edge, and the above failure may therefore occur.

Denoting the target value of the off-angle distribution by “θ1” (deg (degree)) and the target value of the total thickness variation by “t1” (μm), a method of setting the off-angle distribution θ1 to be 0.25 deg or smaller and the difference in the height (the total thickness variation t1) of the Ga face to be 20 μm or smaller, that is an example of this first embodiment, will be described. When the off-angle distribution is 0.1 deg, the wavelength has a dispersion of about 10 nm. For example, for the wavelength of 450 nm of a blue LED, to set the dispersion of the wavelength to be 25 nm or smaller, the off-angle distribution needs to be set to be 0.25 deg or smaller. When the dispersion of the wavelength is larger than 25 nm, the blue color to be an element of a white light disperses and this acts as a cause of color unevenness of the white light. The temperature distribution and the raw material gas distribution can each be set to be uniform when the semiconductor layer is epitaxial-grown on the GaN substrate by reducing the total thickness variation. Any error of each of the exposure patterns can be reduced for the photolithography at the device fabrication steps and, when the total thickness variation is 20 μm or smaller, stable exposure can be conducted. The surface only has to be processed to match with the shape of the warpage of the crystal as above as the reduction of the off-angle distribution while the reduction of the off-angle distribution and the increase of the total thickness variation are in a trade-off relation with each other.

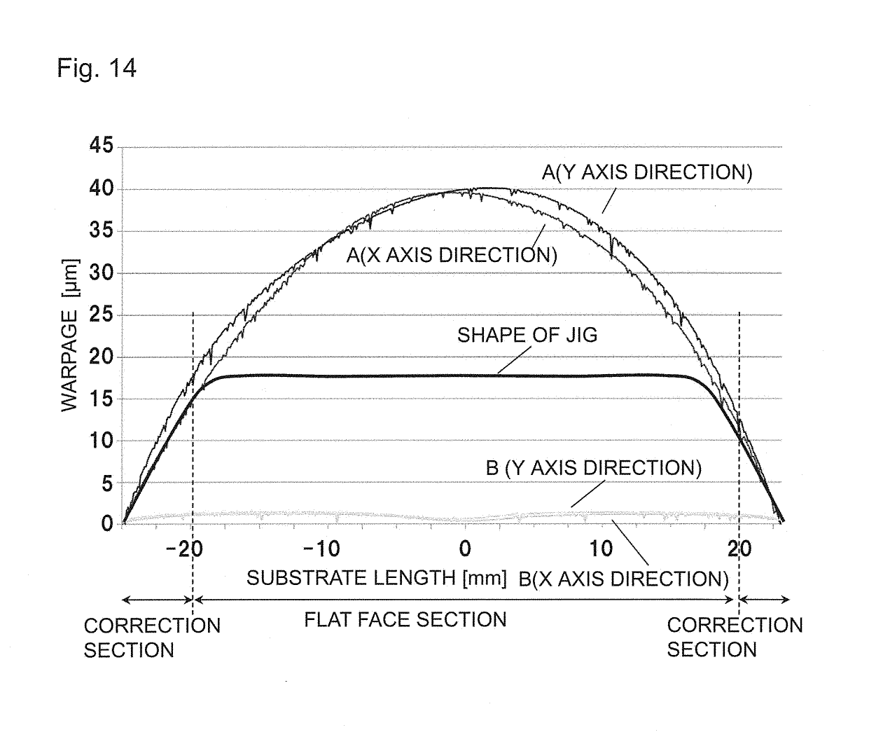

The inventor therefore has conceived of the fact that, in the Ga face of the GaN substrate, a section having small off-angle distribution at the center is set to be a flat face portion having a flat face shape and the outer circumference surrounding the flat face portion is set to be a curved face portion as a correction section for the off-angle to thereby be able to acquire a GaN substrate whose off-angle distribution is reduced and whose total thickness variation is small. For example, as depicted in FIG. 14, a section whose position from the substrate center (0 mm) is −20 mm or smaller and +20 mm or larger is set to be the curved face portion as the correction section for the off-angle. On the other hand, a section whose position from the substrate center is −20 mm to +20 mm has the off-angle distribution present therein while this off-angle distribution is in the permissible range and this section is therefore set to be the flat face section having the flat face shape. The border between the flat face section and the correction section is processed to be a smooth curved line. With the shape as above mentioned, the correction section can reduce the off-angle distribution. On the other hand, the flat face section has the original off-angle and can therefore satisfy the off-angle distribution of 0.25 deg or smaller and the difference in the height of 20 μm or smaller for the overall area thereof. Especially, the shape of the present disclosure is effective for a substrate whose radius is 20 mm or larger.

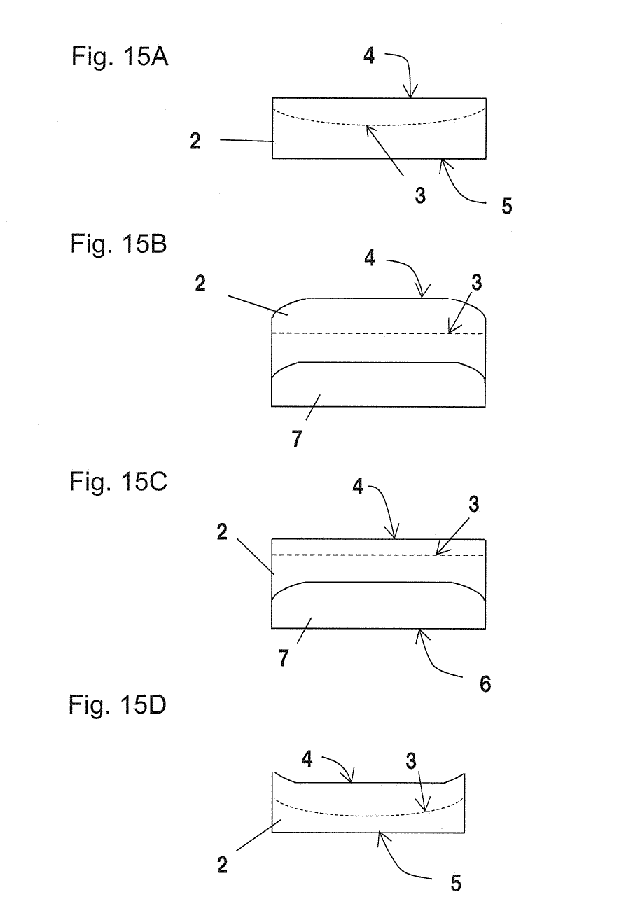

The fabrication method for the GaN substrate 2 according to this first embodiment will be described with reference to FIG. 15A to FIG. 15D.

(a) FIG. 15A is the GaN substrate 2 that has the off-angle distribution. The GaN substrate 2 is already processed by grinding such that the Ga face 4 and the N face 5 of the GaN substrate 2 fabricated using the HYPE method are flat faces parallel to each other. In this case, in the GaN substrate 2, the warpage 3 of the crystal is generated that has the convex shape from the Ga face 4 toward the N face 5 schematically indicated by a dotted line 3 in FIG. 15A. The warpage 3 of the crystal has a concave shape when seen from the side of the Ga face 4.

(b) As depicted in FIG. 15B, the N face 5 of the GaN substrate 2 is pressed to a jig 7 and a load is applied thereto to thereby deform the GaN substrate 2 to fit with the shape of the jig 7 to be attached using a wax. As depicted in FIG. 14, the shape of this jig 7 is formed to satisfy Eq. (5) for the correction section and to have a cross-sectional shape connecting the correction section and the flat face section to each other by a smooth curved line. Because the GaN substrate is pressed to the jig 7, ceramic, an iron-based material, or stainless steel is advantageously used as the material quality of the jig 7. For the attaching of the jig 7 and the GaN substrate 2 to each other, for example, the jig 7 is heated using a hot plate, a thermoplastic wax is applied to the surface of the jig 7, the N face 5 of the GaN substrate 2 and the jig 7 are placed thereon for the N face 5 and the jig 7 to be in contact with each other, a load is applied thereto, and, in this state, the wax is hardened by natural cooling. The warpage 3 of the crystal is thereby set to be a substantially flat face as schematically depicted in FIG. 15B. The warpage 3 of the crystal can substantially be solved.

(c) As depicted in FIG. 15C, the Ga face 4 is ground to be parallel to the reference face 6 and is further polished to remove an affected layer. For the grinding, parallel faces are formed by grinding using a rotary grindstone, and the degree of surface roughness is reduced by lapping using loose grains, flat surface honing using a fixed grindstone, or the like to remove the affected layer using chemical mechanical polishing (CMP) or the like.

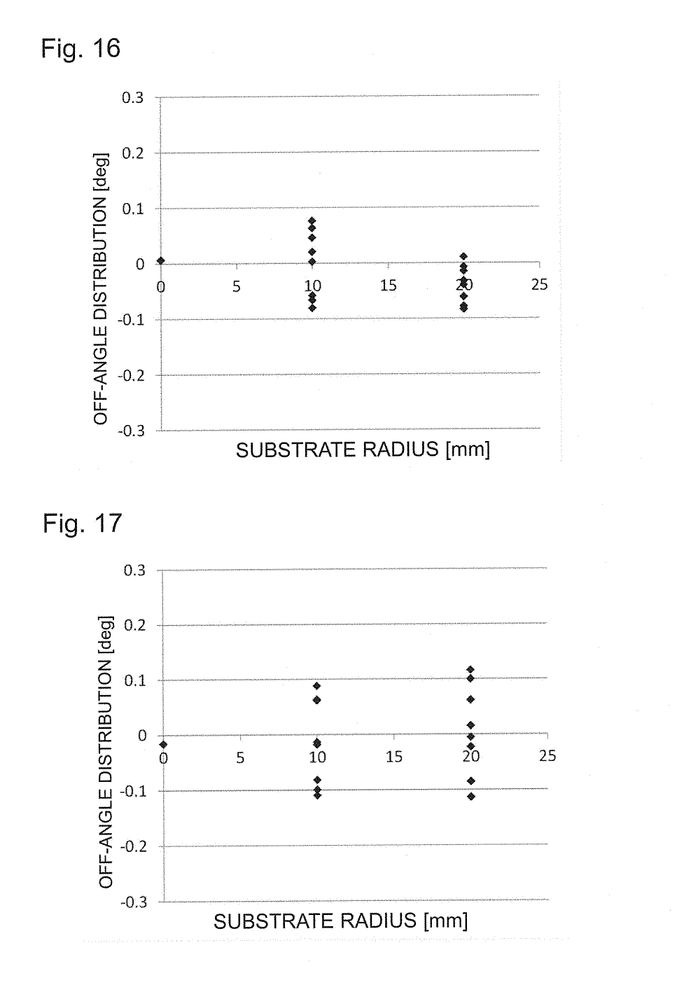

(d) The jig 7 is detached from the GaN substrate 2 to acquire the GaN substrate 2 depicted in FIG. 15D. The off-angle distribution of the GaN substrate 2 fabricated in this manner is 0.25 deg or smaller for the overall area thereof as depicted in FIG. 16 and FIG. 17. FIG. 16 is a diagram of the off-angle distribution in the X-axis direction and FIG. 17 is a diagram of the off-angle distribution in the Y-axis direction.

As above, the flat face section does not mean having no processed flat surface, but the flat face section does merely mean having a flat face shape. The correction section is processed to vary in its thickness direction in corresponding to the position from the center of the substrate.

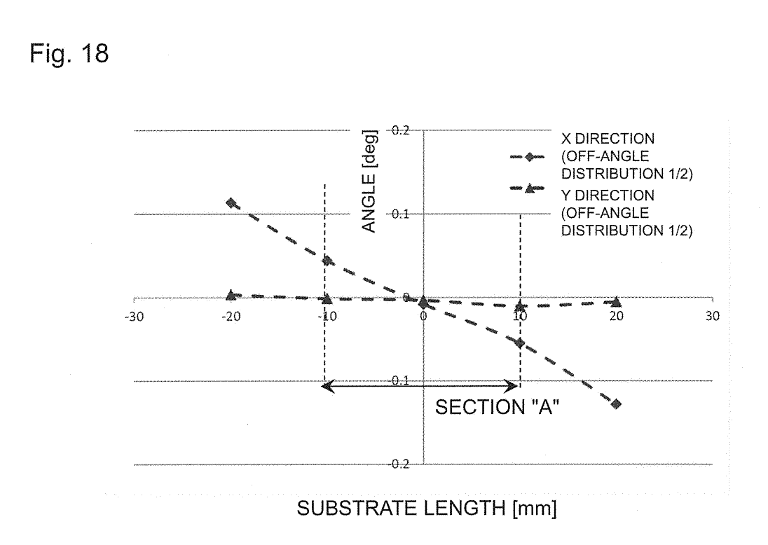

FIG. 18 depicts an off-angle distribution for the case where the off-angle distribution θ1 in the section between the substrate lengths of −20 mm and +20 mm is 0.24 deg. When the off-angle distribution is a ½-fold, the portion of a section “A” (between the substrate lengths of −10 mm and +10 mm) of FIG. 18 is set to be a flat face section and the circumference more outward than the section A is set to be a curved face portion. The difference in the height can thereby be set to be 20 μm or smaller and the off-angle distribution can thereby be set to be 0.1 deg or smaller to enable further improvement of precision. When the off-angle distribution is 0.1 deg or smaller, the dispersion of the wavelength is about 10 nm when the device is formed, and the device is therefore applicable to the use that requires strict precision for the dispersion of the wavelength such as, for example, a laser diode (LD).

Though the description has been made on the premise that the direction of the warpage of the crystal is a concave shape in the above description, this is the shape of the GaN substrate acquired when the GaN substrate is formed using sapphire as the foundation substrate and using the HVPE method. This premise may not be applied when the physical shape of the foundation substrate is varied or when a foundation substrate is used that has physical properties different from those of sapphire.

### MODIFICATION EXAMPLE

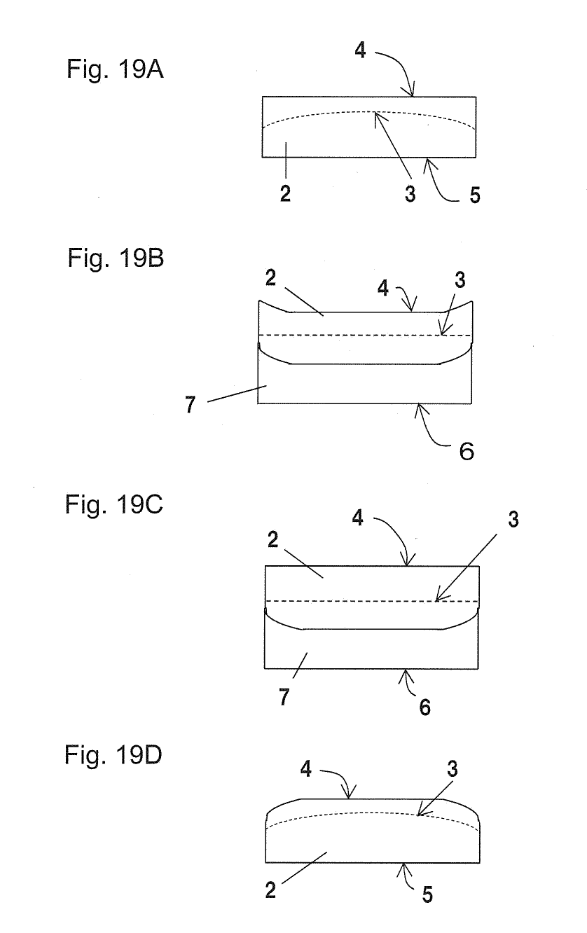

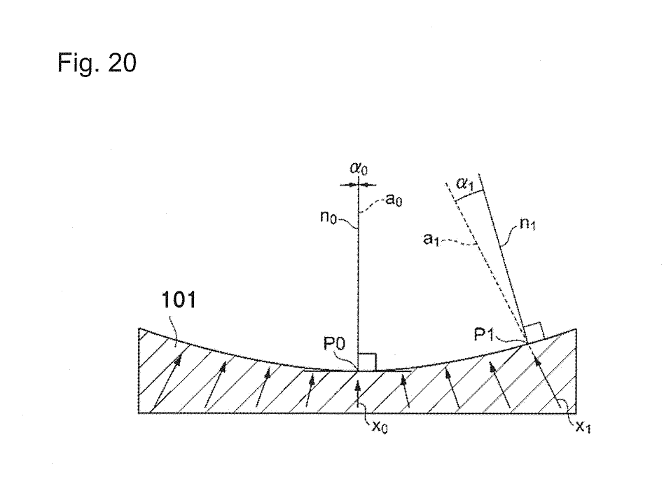

As a modification example, FIG. 19A to FIG. 19D depict a correction method for the off-angle distribution for the case where the warpage 3 of the crystal has a convex shape on the side of the Ga face 4. In this case, as schematically indicated by the dotted line 3 in FIG. 19A, the GaN substrate 2 has the warpage 3 of the crystal of the convex shape from the N face 5 toward the Ga face 4. The jig 7 has a concave shape having a flat face portion at its center, and a curved face portion surrounding the flat face portion on the outer edge, and outer edge of the curved face portion protrudes relative to the flat face portion at the center. The fabrication method for a GaN substrate in this case includes the same steps as those depicted in FIG. 15A to FIG. 15D except the facts that the warpage 3 of the crystal of the GaN substrate is the convex shape and that the shape of the jig 7 is the concave shape. A flat face portion and a curved face portion surrounding the flat face portion are disposed on the GaN substrate by this fabrication method for a GaN substrate. A GaN substrate can thereby be formed such that the off-angle distribution thereof is ±θ1 (deg) or smaller, the off-angle distribution in the curved face portion is ±θ1 (deg) or smaller, and the total thickness variation of the GaN substrate 2 is t1 (μm) or smaller.

As above, the GaN substrate according to the present disclosure is characterized in that the GaN substrate is a substrate whose N face is a flat face, whose Ga face has a flat face portion in the central portion thereof, and a curved face portion surrounding the circumference of the flat face portion. From the viewpoint of the off-angle, the GaN substrate is characterized in that the GaN substrate is a substrate whose off-angle of the N face is larger than the off-angle of the Ga face. Providing this GaN substrate enables reduction of any dispersion of the properties and realization of a device with small dispersion at the epitaxial growth step and at the device formation steps to be the steps conducted thereafter.

The present disclosure includes properly combining any optional embodiments and/or Examples with each other of the above various embodiments and/or Examples, and the effects to be achieved by the combined embodiments and/or Examples can be achieved.

Use for a semiconductor element represented by an LED has been described in the present disclosure while a device with small dispersion of the device properties can also be realized by using this substrate in the fabrication of a power semiconductor element.

### EXPLANATIONS OF LETTERS OR NUMBERS

1 jig
2 GaN substrate
3 warpage of the crystal
4 Ga face
5 N face
6 reference face
7 jig
101 GaN substrate

1. A GaN substrate that comprises a GaN single crystal having a Ga face and a N face on surfaces thereof, wherein the Ga face comprises:
a flat face portion; and
a curved face portion that surrounds a circumference of the flat face portion, and
wherein an off-angle distribution of the N face is larger than an off-angle distribution of the Ga face.

2. The GaN substrate according to claim 1, wherein the off-angle distribution θ1 of the Ga face is 0.25 deg or smaller, and
wherein a total thickness variation t1 of the GaN substrate is 20 μm or smaller.

3. A fabrication method for a GaN substrate, the fabrication method comprising:
preparing a GaN substrate that comprises a GaN single crystal having a Ga face and a N face, the Ga face and the N face being parallel to each other on principal surfaces of the GaN substrate, the principal surfaces facing each other;
causing the N face to face a surface of a jig that comprises a flat face portion at a center thereof and a curved face portion surrounding a circumference of the flat face portion to attach the GaN substrate to the jig;
polishing the Ga face of the GaN substrate to have a flat face shape; and
detaching the jig from the GaN substrate.

4. The fabrication method for a GaN substrate according to claim 3, wherein in the case where warpage of the crystal of the prepared GaN substrate comprises a concave shape when seen from the Ga face, the jig comprises a convex shape that comprises the flat face portion at the center protruded relative to the curved face portion on an outer edge thereof, on the surface thereof.

5. The fabrication method for a GaN substrate according to claim 3, wherein in the case where warpage of the crystal of the prepared GaN substrate comprises a convex shape when seen from the Ga face, the jig comprises a concave shape having the curved face portion on an outer edge thereof protruded relative to the flat face portion at the center thereof, on the surface thereof.

6. The fabrication method for a GaN substrate according to claim 3, wherein a section of the jig corresponding to a section in a range for an off-angle distribution θ1 from the center of the Ga face of the prepared GaN substrate is set to be the flat face portion.

7. The fabrication method for a GaN substrate according to claim 3, wherein the jig comprises a reference face having a flat face shape on a back face thereof that faces the surface, and
wherein at the step of polishing, the Ga face is polished to have a flat face shape to be in parallel to the reference face of the jig.
